(19) United States
(12) Patent Application Publication
(10) Pub. No.: US 2007/0243491 A1
(43) Pub. Date: Oct. 18, 2007

(54) Method of making a semiconductor with a high transmission CVD silicon nitride phase shift mask

(76) Inventors: Wei E. Wu, Austin, TX (US); Jonathan L. Cobb, Austin, TX (US); Bernard J. Roman, Austin, TX (US)

Correspondence Address: HAMILTON & TERRILE, LLP, P.O. BOX 203518, AUSTIN, TX, 78720, US

(21) Appl. No.: 11/406,202

(22) Filed: Apr. 18, 2006

(51) Int. Cl. G03F 7/26

(52) U.S. Cl. 430/311

(57) ABSTRACT

A method for making a semiconductor device includes (a) providing a source of actinic radiation (601), (b) providing a mask formed from (i) a substrate that is substantially transparent to the actinic radiation, and (ii) a plurality of silicon nitride structures formed on the substrate using chemical vapor deposition and selective etching, wherein each silicon nitride structure has a transmission with respect to the actinic radiation that is within the range of about 30% to about 35%, and wherein the combination of each silicon nitride structure and the substrate imparts to the actinic radiation a phase change within the range of about 190° to about 200° (603), and (c) using the mask and the source of actinic radiation to impart a pattern to a semiconductor substrate (607, 609).

### BACKGROUND OF THE INVENTION

1. Field of the Invention

The present invention is directed in general to the manufacture and use of phase shift photolithography masks. In one aspect, the present invention relates to high transmission attenuated phase shift masks.

2. Description of the Related Art

As a result of innovations in integrated circuit and packaging fabrication processes, dramatic performance improvements and cost reductions have been obtained in the electronics industry. The speed and performance of chips, and hence the computer systems that utilize them, are ultimately dictated by the minimum printable feature sizes obtainable through lithography. The lithographic process, which replicates patterns rapidly from one wafer or substrate to another, also determines the throughput and the cost of electronic systems. A typical lithographic system includes exposure tools, masks, resist, and all of the processing steps required to transfer a pattern from a mask to a resist, and then to devices.

As integrated circuit feature sizes decrease, the imaging resolution becomes limited by the diffraction of light at a given wavelength. To address the diffraction problem, phase shift masks have been developed that include patterned mask features to provide destructive optical interference to enhance a mask's resolution and depth of focus. An example of an attenuated phase shift mask technology is chromeless phase lithography (CPL), a particular lithographic technique that uses chromeless mask features to define circuit features with pairs of 0-degree and 180-degree phase steps. These phase steps can be obtained, for example, by etching a trench in a quartz substrate to a depth corresponding to a 180-degree phase shift at the illumination wavelength (that is, the wavelength of the actinic radiation) of the lithography system. Alternatively, phase shift layers can be formed in an embedded mask as mesas on a quartz substrate.

CPL mask designs can be created by assigning circuit features to different zones or groups, based on the physical attributes of those features. One example of such a system, which is known in the art, is depicted in FIGS. 1-2. The system illustrated therein uses three such zones, the boundaries of which are defined herein for illustrative purposes only. In the system, circuit features having widths of 90 nm or less (or having a mask critical dimension less than or equal to 100 nm) are assigned to Zone 1. These features are constructed with 100% transmission phase-shifted structures and are printed using adjacent phase edges. Hence, these features are chromeless features. Features having a width greater than 130 nm (or having a mask critical dimension greater than 150 nm) are deemed to reside in Zone 3, and are printed using chrome features. Features having widths between 90 nm and 130 nm (or having a mask critical dimensions between 100 nm and 150 nm) are deemed to reside in Zone 2. The features of Zone 2 are too wide to be defined using the 100% transmission of pure CPL and may be too narrow to be printed solely in chrome, and hence are printed using a so-called “zebra” pattern treatment. The zebra pattern treatment employs a plurality of sub-resolution chrome patches which are formed on the chromeless feature pattern to be imaged and which are intended to reduce the average optical transmission of the otherwise chromeless feature. If correctly defined on the mask, the zebra pattern treatment can result in improved lithographic margins for features that reside in Zone 2 compared to either chromeless or chrome features.

While CPL processes of the type depicted in FIGS. 1-2 have some desirable attributes, the zebra pattern treatment step used in these processes contains structures that are sub-resolution. Moreover, the zebra structures are secondary features formed in a second writing step which typically involves use of an optical pattern generator (the first writing step being an electron beam pattern generator used to form the primary, chromeless features). Hence, the sub-resolution features in the zebra structures may not be formed using a high resolution pattern generator, and must also be registered with the primary, chromeless features. Consequently, the mask used to form these structures is difficult to fabricate, inspect and repair. The zebra structures also significantly increase the size of the pre- and post-fracture database, making fabrication of the mask a computationally intensive undertaking. Moreover, critical dimension (CD) uniformity and control on zebra structures has proven to be less than desirable.

Other phase shifting masks are also known in the art that are somewhat similar to the mask described above and that attenuate and change the phase of transmitted light by 180° relative to the incident light. While a number of materials have been proposed that may meet these transmission and phase requirements, the materials are typically deposited as a multi-layer film stack to control transmission and phase independently. For example, FIG. 3 illustrates a mask 101 that comprises a quartz substrate 103 having a plurality of 30% transmission features 105 disposed thereon. Each feature 105 comprises one or more attenuation layers 107 (e.g., MoSi, Cr, Ta or TaHf) with a phase shift layer 109 (e.g., SiON or SiO₂) disposed thereon. Masks of this type have been proposed as stand-alone solutions for so-called “high transmission” attenuated phase shifting masks, but such masks have proven difficult to fabricate. Process and performance limitations, such as process window loss, are also associated with three-dimensional mask effects from such multi-layer masks. Even the simpler, single layer mask technologies use unnecessarily complex fabrication processes to provide a phase shift of 180°, as seen in U.S. Patent Publication No. 2002/0197509A1 to Carcia et al., but such technologies do not allow for precise tuning or adjustment of the degree of phase shift.

Accordingly, a need exists for a high transmission phase shift mask design, and a process for making the same, which provides the mask transmission and phase shift requirements using a single layer to control and optimize the phase and transmission. There is also a need for a simplified phase shift mask that can be readily fabricated. In addition, there is a need for a mask fabrication process which avoids the process and performance limitations associated with thick, multi-layer masks or with unduly complex fabrication processes. In addition, there is a need for improved mask fabrication processes and devices to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 is a graph of wafer critical dimensions as a function of mask critical dimensions for a prior art CPL process;

FIG. 2 is an illustration of a prior art 3-zone CPL process;

FIG. 3 is an illustration of a portion of a prior art mask;

FIG. 4 is a partial cross-sectional view of a mask blank having a plurality of layers, including a silicon nitride layer, formed on a substrate;

FIG. 5 illustrates processing subsequent to FIG. 4 after a first layer of photoresist is patterned and etched;

FIG. 6 illustrates processing subsequent to FIG. 5 after a metal mask layer is selectively etched;

FIG. 7 illustrates processing subsequent to FIG. 6 after the silicon nitride layer is selectively etched;

FIG. 8 illustrates processing subsequent to FIG. 7 after a second layer of photoresist is deposited;

FIG. 9 illustrates processing subsequent to FIG. 8 after the second layer of photoresist is patterned and etched;

FIG. 10 illustrates processing subsequent to FIG. 9 after exposed metal layer features are removed;

FIG. 11 is a graph of critical dimension variation as a function of pitch for CDs of 70 nm; and

FIG. 12 is a flowchart of one embodiment of fabricating a semiconductor device in accordance with the teachings herein.

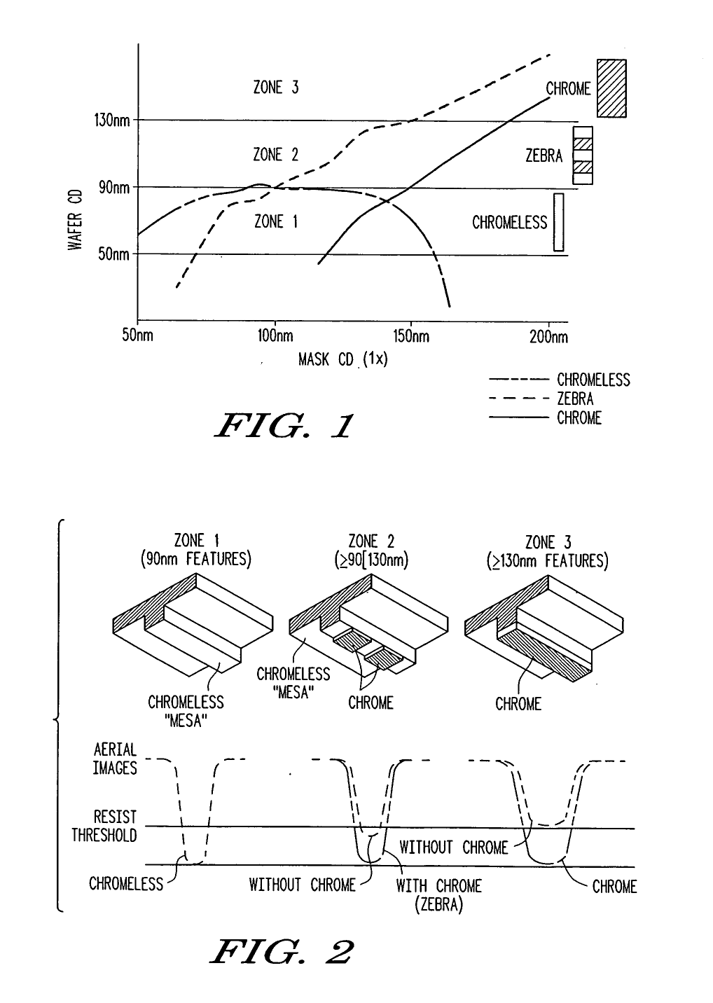

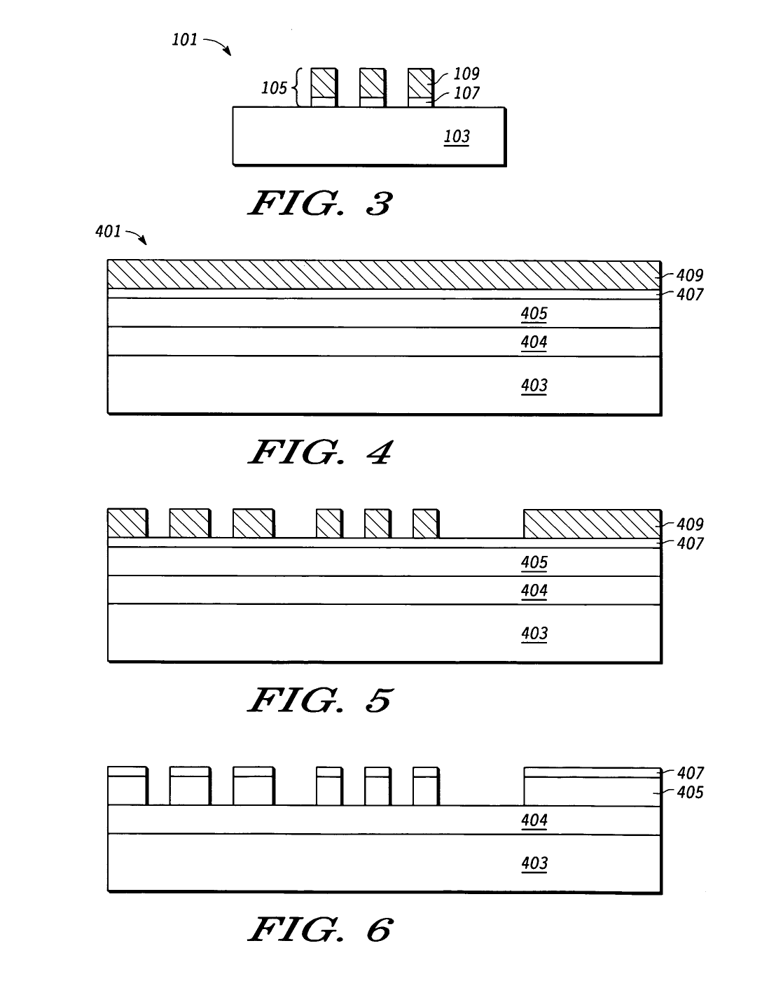

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A method and apparatus are described for fabricating high transmission attenuated phase shift masks by using silicon nitride as a mask layer that simultaneously provides the transmission and phase requirements. For example, a silicon nitride layer formed with a chemical vapor deposition (CVD) process over a quartz substrate is etched to form attenuated etched mask features that provide a controllable and optimized phase shift (e.g., approximately 190-200° ) and transmission (e.g., in the range of 10-40%). Because CVD silicon nitride has been widely used in wafer fabrication, its optical and stoichiometric properties are well known, allowing the film deposition and etch processes for this material to be used in the mask fabrication process. In a selected embodiment, masks are formed using an optically-tunable silicon-rich nitride (SiRN) layer that has been developed and successfully used in the industry for anti-reflection coatings to reduce unwanted reflections in wafer lithography. As a result working with a well understood material, the optical constants—thickness (t), refraction index (n), extinction coefficient (k) and transmission (T)—may be readily controlled to tune or adjust the degree of phase shift provided by the silicon nitride layer. In addition to providing both mask absorption and phase shifting properties, the high refractive index of silicon nitride allows masks to be formed with significantly reduced total film thickness, thereby minimizing process window loss due to 3-D mask effects.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of a wafer mask without including every feature or geometry in order to avoid limiting or obscuring the present invention. It is also noted that, throughout this detailed description, certain materials will be formed and removed to fabricate the mask. Where the specific procedures for forming or removing such materials are not detailed below, conventional techniques to one skilled in the art for growing, depositing, removing or otherwise forming such layers at appropriate thicknesses shall be intended. Such details are well known and not considered necessary to teach one skilled in the art of how to make or use the present invention.

While the masks described herein can be fabricated in a variety of different ways, an illustrative example is depicted in the mask fabrication process flow illustrated beginning with FIG. 4 which illustrates a partial cross-sectional view of a mask blank 401 having a plurality of layers, including a quartz substrate 403, a silicon nitride layer 404, a layer of chrome 405, an antireflective layer 407, and a first layer of photoresist 409. In a selected embodiment, the substrate 403 is formed from quartz. The silicon nitride layer may be formed from an optically-tunable silicon-rich nitride, and may be deposited using any desired uniform deposition technique—such as chemical vapor deposition (CVD), physical vapor deposition (PVD), or atomic layer deposition (ALD)—to a thickness of approximately 65 nm, though other thicknesses (e.g., approximately 60-70 nm) may be used, depending on the particular application. Chrome may be used for the metal 405 and may be formed to a thickness of approximately 50 to 80 nm (e.g., 70 nm), while the anti-reflective coating layer 407 may be formed from CrₓO_{y} (e.g., CrON) to a thickness of approximately 15-25 nm (e.g., 20 nm), though other thicknesses may be used. The first layer of photoresist 409 preferably comprises a suitable e-beam lithography resist such as, for example, NEB22 (a negative tone resist available commercially from Sumitomo Corporation, Tokyo, Japan), or FEP171 (a positive tone resist available from Fujifilm Electronic Materials U.S.A. Inc., North Kingstown, R.I.).

Referring to FIG. 5, a first pattern is defined in the first layer of photoresist 409 using suitable lithographic techniques. The first pattern corresponds to the etched SiN components or mesas that are to be formed as part of the final mask (depicted in FIG. 10). This step, which is one of two writing steps employed in the method and which is used to define the primary mask features, may be accomplished, for example, through the use of suitable e-beam writing techniques as are known to the art. This step will typically include nominal registration of the first pattern with the edges of the mask.

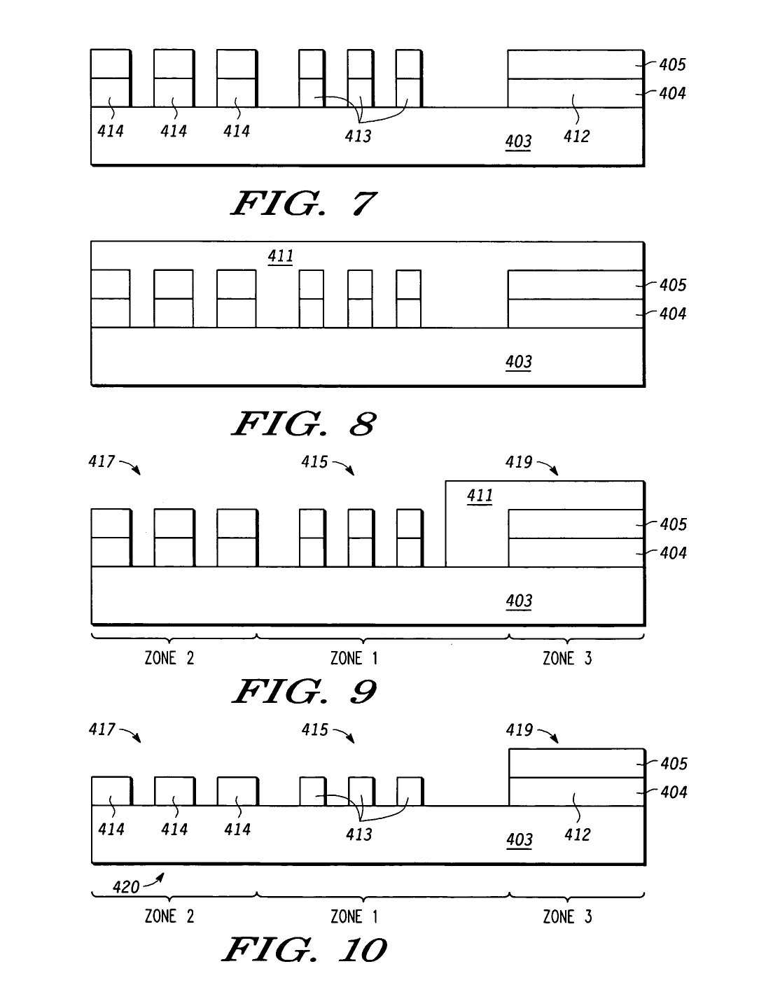

Using the first layer of photoresist 409 as an etch mask, the antireflective layer 407 and the underlying metal layer 405 are subsequently etched down to the silicon nitride layer 404 through the use of a suitable etchant, as shown in FIG. 6, after which the first layer of photoresist 409 is stripped. Then, as shown in FIG. 7, the silicon nitride layer 404 is etched down to the quartz substrate 403 by using the patterned metal layer 405 as an etch mask, and with the use of a suitable etchant that is selective to the metal layer, which typically is chrome. This etch imparts a first pattern in the silicon nitride layer 404 which is a series of chrome-capped silicon nitride mesas 412, 413, 414 on the substrate 403, as shown in FIG. 7. The antireflective layer 407 is typically removed during the silicon nitride etch, as shown in FIG. 7.

With reference to FIG. 8, a second layer of photoresist 411 is then deposited over the structure. The second layer of photoresist 411 is preferably an optical resist upon which a second pattern is written through optical exposure. As shown in FIG. 9, the second layer of photoresist 411 is selectively removed from over the Zone 1 features 415 and Zone 2 features 417, but is left over the Zone 3 features 419. This step is the second of two writing steps employed in the method, and is used to define the secondary mask features. Typically, this second writing step will also require registration of the second pattern with the first pattern.

As depicted in FIG. 10, the chrome layer 405 is then removed from the exposed portion of the mask through etching, and the second layer of photoresist 411 is stripped. The resulting mask 420 depicted in FIG. 10 includes a substrate 403 on which Zone 1 features 415 are formed from uncapped silicon nitride mesas 413 having a first predetermined mask critical dimension (e.g., between 50 nm and 100 nm). The mask 420 also includes Zone 2 features 417 formed from uncapped silicon nitride mesas 414 having a second, wider predetermined mask critical dimension (e.g., between 100 nm and 150 nm). In addition, Zone 3 features 419 are also formed from chrome-capped silicon nitride mesas 412 having a third predetermined mask critical dimension (e.g., between 150 nm and 200 nm). The Zone 1 features 415 and Zone 2 features 417 are formed on a 100% transmission substrate 403 as a plurality of etched silicon nitride structures 413, 414 that provide an optimized, nominal phase shift (e.g., 190-200°) to any actinic radiation considering the 3-D effects of mask topology, and an intermediate (e.g., 30-35%) transmission with respect to the actinic radiation passing through the substrate 403. The Zone 3 features 419 are formed on a 100% transmission substrate 403 as silicon nitride structures 412 capped with an opaque material 405, thereby creating essentially 0% transmission structures. In the example embodiment depicted, the opaque material is a 50-80 nm thick layer of chrome. After the mask 420 is formed, it may be used to transfer the patterns written on it to a chip, wafer or other substrate, typically through the use of a reduction stepper.

It has been found that silicon nitride structures (that is, structures that reduce the transmission of the underlying substrate without rendering it entirely opaque) can be used for at least Zone 1 and Zone 2 features on a phase shift mask. The silicon nitride structures are readily manufactured because silicon nitride has been widely used in wafer fabrication, and its optical and stoichiometric properties are well known. Moreover, the silicon nitride structures provide better CD control than chromium zebra structures known in the art which require sub-resolution components. In addition, the silicon nitride structures can be configured with transmission (e.g., 30%) and phase difference (e.g., 195°) characteristics that are optimized for lithographic process windows and/or critical dimension control. It will be appreciated that the silicon nitride structures described herein can be combined on the same reticle with with pure CPL features having 100% transmission.

Various modifications and substitutions may be made to the particular embodiment described above without departing from the scope of the teachings herein. For example, while a selected embodiment employs CVD silicon nitride as a combined mask absorber and phase shift material, it will be appreciated that the particular material used, and the thickness of that material, may vary from one application to another. In addition, while the silicon nitride structures 412-414 may be formed by etching trenches into a CVD deposited layer of silicon nitride 404 having a thickness of approximately 60-70 nm, it will be appreciated that the appropriate layer thickness depends on the optical properties desired and the source of actinic radiation, and may vary from one application to another. Preferably, however, the choice of material, and the layer thickness of that material, will be selected to provide an optical transmission of the actinic radiation through the layer of about 5% to about 50%, more preferably about 15 to about 40%, and most preferably about 30% to about 35%. The choice of material, and the layer thickness of that material, will also preferably be selected to provide the attenuating structure (and any trenches or mesas which form a part thereof) with the ability to impart to the actinic radiation a phase change of about 165° degrees to about 225°, more preferably of about 175° to about 215°, even more preferably of about 185° to about 205°, and most preferably of about 195°.

In embedded mask applications, it is contemplated that the phase change and transmission properties of the silicon nitride structures depend on the indices of refraction (and more particularly, the differences in index of refraction) and extinction coefficients of the silicon nitride material and/or the substrate, and hence could also be described in terms of these parameters. The phase change and transmission properties associated with a given set of indices of refraction and extinction coefficients may be determined, for example, through suitable simulations and/or calculations. In an illustrative embodiment, a 70 nm thick silicon nitride layer having an extinction coefficient k of approximately 0.26 to 0.28 (and more specifically, 0.27) and an index of refraction n of approximately 2.4 to 2.5 provides a phase shift of approximately 190° and a transmission of between approximately 30-35 percent. As will be appreciated, the specific phase shift and transmission obtained by a given layer of silicon nitride will depend on the selection of the optical constant value, taking into account the multiple reflections between the silicon nitride layer and the quartz substrate.

The use of chrome in the embodiment described above is advantageous in that chrome has a very low optical transmission (i.e., a very high opacity) with respect to 193 nm wavelengths and other commonly used sources of actinic radiation, even at fairly thin layer thicknesses, and hence functions well as an absorber on the mask 420. Moreover, a number of metal etchants are available that exhibit good selectivity between chrome and silicon nitride. This allows chrome to be selectively removed from the Zone 1 and Zone 2 silicon nitride structures 413, 414. However, it will be appreciated that other materials, or combinations of materials, that provide these functionalities may be used in place of chrome and/or in conjunction with the silicon nitride material, including, but not limited to, titanium and tungsten, and various combinations, mixtures, salts, compounds, or alloys of the foregoing. Moreover, in some embodiments, a first material with the requisite opacity may be used in conjunction with a second material that can function as a suitable etch mask. In addition, one or more stress compensation layers may be provided between the opaque material (e.g., chrome) and the silicon nitride layer (and removed during chrome etch). Such stress compensation layers may comprise, for example, silicon oxynitride or other suitable stress compensating materials as are known to the art. Likewise, various barrier layers may be used in the structures described herein to impart etch selectivity to various layers, or for other purposes.

Unless otherwise specified, the embodiments described herein assume actinic radiation having a wavelength of 193 nm. It will be appreciated, however, that the teachings herein are not limited to a specific wavelength of actinic radiation. Moreover, one skilled in the art will appreciate that the structures and methodologies described herein could be adapted to operate at more than one wavelength of actinic radiation. For example, embodiments are contemplated herein in which the opaque layer and attenuating layer are adapted to operate at either 193 nm or 248 nm. This would allow blanks to be provided that work at multiple wavelengths of commonly used actinic radiation.

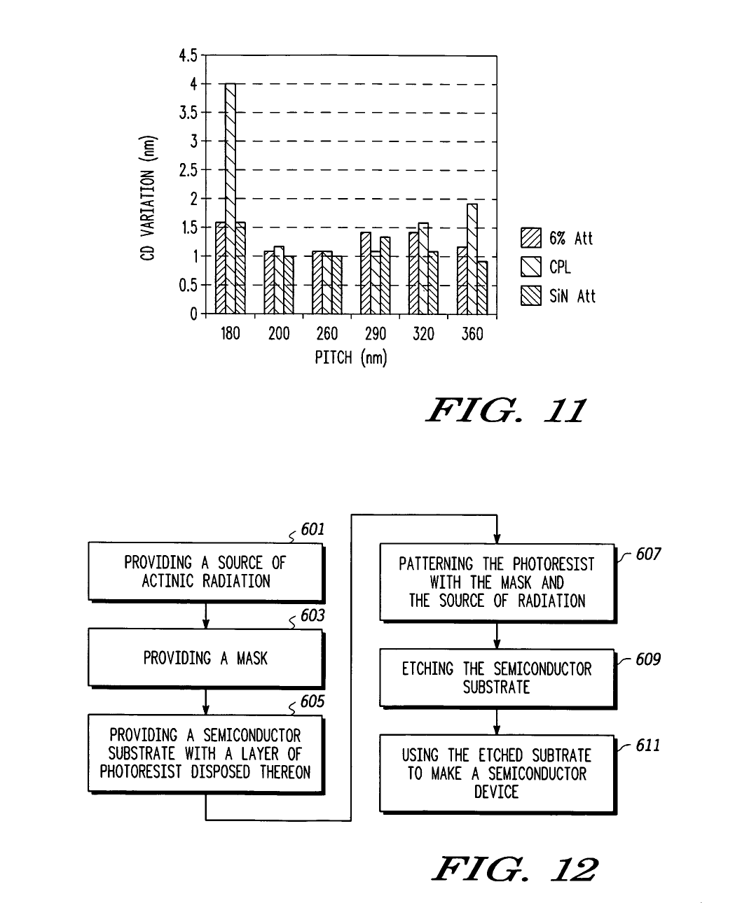

FIG. 11 provides an example illustration of the improvements in critical dimension control for critical dimensions of 70 nm that may be obtained with the CVD silicon nitride structures described herein, and as compared to chromeless and prior art attenuated structures. In particular, FIG. 11 illustrates the CD variation (in nanometers) as a function of pitch for Monte Carlo simulations of 70 nm lines obtained lithographically using the silicon nitride mask techniques described herein (denoted SiN Att). For comparison, the CD variation of features made using CPL alone (denoted CPL), and the CD variation of a commercially available 6% EAPSM mask (denoted 6% Att) are also provided at various pitches. The simulation assumed a silicon nitride structure having a thickness of 65 nm and a transmission of 30% and a phase transmission of 190°. The simulation testing further assumed a full resist model with an exposure tool having QUASAR illumination, and having a numerical aperture of 0.85, a normalized outer radius of 0.87, a normalized inner radius of 0.57, and a 30° opening or pole angle. All simulations assume that the process is centered on printing a 70 nm nominal line width at 260 nm pitch. The standard deviation in dose in the exposure tool (1σ dose) is assumed to be 1%, the standard deviation in focus (1σ defocus) of the tool is assumed to be 40 nm, and the standard deviation in mask critical dimension (1σ mask CD) is assumed to be 0.67 nm (at 1×). The pitch referred to here is the sum of line width and spacing (that is, the spacing between adjacent lines).

As this graph illustrates, the silicon nitride structures provide CD control that is superior to that of CPL in all of the ranges simulated, except for CPL structures at 290 nm where the silicon nitride structures are comparable. It is also to be noted that the CD control provided by the silicon nitride structures at 200 nm, 260 nm, 290 nm, 320 nm and 360 nm is superior to the CD control provided by 6% EAPSM structures, while the CD control provided by the silicon nitride structures at 180 nm is at least comparable to the CD control provided by 6% EAPSM structures. Hence, these results demonstrate that the silicon nitride structures are a viable alternative to CPL and 6% EAPSM structures under certain conditions and at certain pitches.

The use of the phase shift masks described herein in making a semiconductor device may be understood with reference to the flowchart depicted in FIG. 12. As shown therein, such a method will typically involve providing a suitable source of actinic radiation as shown in step 601. As previously noted, common sources of actinic radiation produce wavelengths of 193 nm or 248 nm, although the methods disclosed herein are not particularly limited to a specific wavelength of actinic radiation. As shown in step 603, a mask is provided. Such a mask is of the type described herein, specific examples of which include the mask depicted in FIG. 10. As shown in step 605, a semiconductor substrate is then provided which has a layer of photoresist disposed thereon. The layer of photoresist is patterned through the use of the mask and the source of actinic radiation as shown in step 607. The patterned photoresist is then used as an etch mask to impart the mask pattern (or a negative thereof) to a substrate, as shown in step 609. The etched substrate is then used to make a semiconductor device, as shown in step 611.

In one form, there is provided herein a method for making a semiconductor device which includes providing a source of actinic radiation to illuminate a mask, thereby imparting a pattern to a semiconductor substrate. The mask is formed with a substantially transparent substrate (e.g., quartz) and a plurality of silicon nitride structures that are formed on the substrate using a CVD process to form a layer of silicon nitride that is selectively etched to form patterned silicon nitride structures. The silicon nitride structures, when not capped with an opaque layer, may be used to form a first set of phase-shifting structures which provide, in the pattern areas, intermediate transmission (e.g., approximately 7-50%, and more particularly 30-40%, transmission of at least one polarization of the actinic radiation) in combination with a nominal 180° (and more particularly within the range of about 185-215°) phase shift, and at the same time provide in the clear areas, high transmission lithography structures having greater than about 95% transmission of at least one polarization of the actinic radiation. In a selected embodiment, the combination of each uncapped silicon nitride structure and the substrate imparts to the actinic radiation a phase change within the range of about 190° to about 200°. As the width of the silicon nitride structures decreases, the width of the circuit features patterned thereby also decreases. To obtain circuit features of differing widths, the plurality of silicon nitride structures includes a first set of uncapped silicon nitride structures having a first predetermined mask critical dimension (e.g., between 50 nm and 100 nm). In addition, the plurality of silicon nitride structures includes a second set of uncapped silicon nitride structures having a second wider predetermined mask critical dimension (e.g., between 100 nm and 150 nm). The plurality of silicon nitride structure may also include a third set of silicon nitride structures having a third predetermined mask critical dimension (e.g., at least 150 nm) that are capped with an opaque material, such as chrome. With the third set of silicon nitride structures that are completely covered by a material that is opaque to actinic radiation (such as a chrome capping layer), there is provided in the pattern areas approximately 0% transmission, and in the clear areas, high transmission lithography structures having greater than about 95% transmission. The mask pattern may be transferred by depositing photoresist over the semiconductor substrate, applying the mask to the photoresist-covered substrate, and then illuminating the mask with an appropriate light source (e.g., actinic radiation) to impart the mask pattern to the photoresist, thereby developing the exposed photoresist and exposing the semiconductor substrate under the undeveloped photoresist for subsequent removal (e.g., by etching).

In another form, there is provided a method for making a high transmission phase shift mask by providing a substantially transparent substrate on which is formed a layer of CVD silicon nitride at a predetermined thickness and an opaque layer that is substantially opaque to the actinic radiation. The opaque layer and silicon nitride layer are selectively etched to form a plurality of silicon nitride structures on the substrate. As formed, the predetermined thickness of the silicon nitride layer (e.g., within the range of about 65 to 70 nm) is selected to provide each silicon nitride structure with a transmission with respect to a provided source of actinic radiation that is within the range of about 7% to about 50%, and where each silicon nitride structure combination with the substrate imparts to the actinic radiation a phase change within the range of about 185° to about 215°. The plurality of silicon nitride structures may include a first set of uncapped silicon nitride structures having a first predetermined mask critical dimension, a second set of uncapped silicon nitride structures having a second predetermined mask critical dimension that is wider than the first predetermined mask critical dimension, and a third set of silicon nitride structures capped with an opaque material and having a third predetermined mask critical dimension that is wider than the second predetermined mask critical dimension.

In yet another form, there is provided a method for making a semiconductor device providing a source of actinic radiation and a mask to impart a pattern to a semiconductor substrate. The mask includes a transparent substrate on which is formed a first set of uncapped silicon nitride features adapted to produce device features having a critical dimension CD within the range of 0<CD<k. Also formed on the transparent substrate are a second set of uncapped silicon nitride features that are adapted to produce device features having a critical dimension k≦CD<m. In addition, a third set of capped silicon nitride features may be formed on the transparent substrate, where the third set of capped silicon nitride features are adapted to produce device features having a critical dimension CD≧m, where k and m are real number dimensions. As formed, each uncapped silicon nitride feature has a transmission with respect to the actinic radiation that is within the range of about 7% to about 50%, and wherein the combination of each uncapped silicon nitride feature and the substrate imparts to the actinic radiation a phase change within the range of about 185° to about 215°. In addition, the combination of the uncapped silicon nitride features and the substrate imparts to the actinic radiation a phase change within the range of about 190° to about 200°.

Although the described exemplary embodiments disclosed herein are directed to various phase shifting photolithography masks and methods for making same, the present invention is not necessarily limited to the example embodiments which illustrate inventive aspects of the present invention that are applicable to a wide variety of mask fabrication processes and/or structures. Thus, the particular embodiments disclosed above are illustrative only and should not be taken as limitations upon the present invention, as the invention may be modified and practiced in different but equivalent manners apparent to those skilled in the art having the benefit of the teachings herein. For example, the optical characteristics of the silicon nitride layer may be adjusted to control and tune the phase shift and/or transmission properties using different values than those disclosed. Moreover, the thickness of the described layers may deviate from the disclosed thickness values. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. For example, the silicon nitride structures can be used in place of the chrome zebra structures on a CPL mask, and are easier to manufacture because, unlike the zebra structures known in the art, they do not require sub-resolution components. Moreover, the silicon nitride-based attenuated features provide better CD control than chromium zebra structures in many situations. In addition, the silicon nitride-based attenuated features can be configured with appropriate phase difference (e.g., approximately 190°) and transmission (e.g., 30-35%) characteristics, and can be combined on the same mask with pure CPL features having 100% transmission if additional mask processing steps are implemented. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for making a semiconductor device, comprising:
providing a source of actinic radiation;
providing a mask comprising (a) a substrate that is substantially transparent to the actinic radiation, and (b) a plurality of silicon nitride structures formed on the substrate using chemical vapor deposition and selective etching, wherein each silicon nitride structure has a transmission with respect to the actinic radiation that is within the range of about 7% to about 50%, and wherein the combination of each silicon nitride structure and the substrate imparts to the actinic radiation a phase change within the range of about 185° to about 215°; and
using the mask and the source of actinic radiation to impart a pattern to a semiconductor substrate.

2. The method of claim 1, wherein the step of using the mask and the source of actinic radiation to impart a pattern to a semiconductor substrate comprises:
depositing a layer of photoresist over the semiconductor substrate;
imparting a pattern from the mask to the layer of photoresist through the use of the source of actinic radiation, the pattern exposing a portion of the semiconductor substrate; and
etching the exposed portion of the semiconductor substrate.

3. The method of claim 1, wherein the plurality of silicon nitride structures comprises first and second sets of structures, wherein the first set of structures are formed from uncapped silicon nitride structures, and wherein the second set of structures comprise an opaque capping layer.

4. The method of claim 3, wherein the uncapped silicon nitride structures have a transmission within the range of about 30% to about 40% for at least one polarization of the actinic radiation, and wherein the second set of structures have approximately 0% transmission to the actinic radiation.

5. The method of claim 3, where the plurality of silicon nitride structures comprises a third set of structures comprising uncapped silicon nitride structures that are wider than the first set of structures.

6. The method of claim 1, where the plurality of silicon nitride structures comprises a first set of uncapped silicon nitride structures having a first predetermined mask critical dimension and a second set of uncapped silicon nitride structures having a second wider predetermined mask critical dimension.

7. The method of claim 6, where the first predetermined mask critical dimension is between 50 nm and 100 nm.

8. The method of claim 7, where the second predetermined mask critical dimension is between 100 nm and 150 nm.

9. The method of claim 6, where the plurality of silicon nitride structures comprises a third set of silicon nitride structures capped with an opaque material and having a third predetermined mask critical dimension.

10. The method of claim 9, where the third predetermined mask critical dimension is as at least 150 nm.

11. The method of claim 9, where the opaque material is chrome.

12. The method of claim 1, wherein the combination of the silicon nitride structures and the substrate imparts to the actinic radiation a phase change within the range of about 185° to about 215°.

13. The method of claim 1, wherein the combination of the silicon nitride structures and the substrate imparts to the actinic radiation a phase change within the range of about 190° to about 200°.

14. The method of claim 1, wherein the substrate is a quartz substrate.

15. A method for making a high transmission phase shift mask, comprising:
providing a substrate that is substantially transparent to the actinic radiation;
forming a layer of silicon nitride at a predetermined thickness over the substrate using a chemical vapor deposition process;
forming an opaque layer that is substantially opaque to the actinic radiation; and
selectively etching the opaque layer and silicon nitride layer to form a plurality of silicon nitride structures on the substrate, where the predetermined thickness of the silicon nitride layer is selected to provide each silicon nitride structure with a transmission with respect to a provided source of actinic radiation that is within the range of about 7% to about 50%, and where each silicon nitride structure combination with the substrate imparts to the actinic radiation a phase change within the range of about 185° to about 215°.

16. The method of claim 15, where the plurality of silicon nitride structures comprises:
a first set of uncapped silicon nitride structures having a first predetermined mask critical dimension;
a second set of uncapped silicon nitride structures having a second predetermined mask critical dimension that is wider than the first predetermined mask critical dimension; and
a third set of silicon nitride structures capped with an opaque material and having a third predetermined mask critical dimension that is wider than the second predetermined mask critical dimension.

17. The method of claim 16, where the predetermined thickness of the layer of silicon nitride layer is within the range of about 65 to 70 nm.

18. A method for making a semiconductor device, comprising:
providing a source of actinic radiation;
providing a mask comprising a substrate on which is formed (a) a first set of uncapped silicon nitride features adapted to produce device features having a critical dimension CD within the range of 0<CD<k, (b) a second set of uncapped silicon nitride features adapted to produce device features having a critical dimension k≦CD<m, and (c) a third set of capped silicon nitride features adapted to produce device features having a critical dimension CD≧m, where k and m are real number dimensions; and
using the mask and the source of actinic radiation to impart a pattern to a semiconductor substrate.

19. The method of claim 18, wherein each uncapped silicon nitride feature has a transmission with respect to the actinic radiation that is within the range of about 7% to about 50%, and wherein the combination of each uncapped silicon nitride feature and the substrate imparts to the actinic radiation a phase change within the range of about 185° to about 215°.

20. The method of claim 18, wherein the combination of the uncapped silicon nitride features and the substrate imparts to the actinic radiation a phase change within the range of about 190° to about 200°.
